(19) United States
(12) Patent Application Publication
(10) Pub. No.: US 2010/0319980 A1
(43) Pub. Date: Dec. 23, 2010

(54) PRINTED CIRCUIT BOARD

(76) Inventors: Hyung Ho KIM, Incheon (KR); Dek Gin Yang, Chungcheongbuk-do (KR); Myung Gun Chong, Gyeongsangnam-do (KR); Jung Soo Kim, Gyunggi-do (KR); Won Woo Cho, Busan (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/650,474

(22) Filed: Dec. 30, 2009

(30) Foreign Application Priority Data
Jun. 23, 2009 (KR) 10-2009-0056032

(51) Int. Cl. H05K 1/11; H05K 1/00

(52) U.S. Cl. 174/266; 174/250

(57) ABSTRACT

Disclosed herein is a printed circuit board. When power layers for supplying different voltages are sequentially stacked, a first EBG cell formed between a first power layer and a ground layer is arranged within a second EBG cell formed between a second power layer and the ground layer to allow the first EBG cell and the second EBG cell to have a double EBG structure. Accordingly, the present invention can prevent a DC open state while preventing noise and realizing band-stop characteristics.

### CROSS REFERENCE TO RELATED APPLICATION(S)

This application claims the benefit of Korean Patent Application No. 10-2009-0056032, filed on Jun. 23, 2009, entitled “Printed Circuit Board”, which is hereby incorporated by reference in its entirety into this application.

### BACKGROUND OF THE INVENTION

1. Technical Field

The present invention relates to a printed circuit board.

2. Description of the Related Art

Recently, wired/wireless broadcasting and communication-related technologies and services have rapidly developed.

Accordingly, as the clock frequency of a printed circuit board (hereinafter referred to as a “PCB”) falls within a range of GHz, problems such as Power Integrity (PI), Signal Integrity (SI) and Electromagnetic Interference (EMI), attributable to simultaneous switching noise (hereinafter referred to as “SSN”) which occurs in a variety of types of ON/OFF chips or packages such as digital blocks disposed on a multi-layer PCB, have been highlighted as an important issue in the design of PCBs.

Meanwhile, one of the most popular methods for solving problems such as the influences of PI/SI and the occurrence of EMI attributable to SSN occurring in high-speed digital systems is to connect a Decoupling Capacitor (DP) between a power layer and a ground layer.

However, since a large number of DPs is required in order to reduce SSN, there are problems in that the production costs of PCBs increase, and, additionally, DPs occupy a large proportion of the space of a PCB, and thus a variety of different devices cannot be freely arranged on the PCB.

Further, there occurs a problem because, in a high-frequency band of 1 GHz or more, the reduction of noise cannot be effectively performed.

Accordingly, in order to solve the problem of SSN in a GHz band, an electromagnetic band gap (hereinafter referred to as “EBG”) structure having a frequency selection capability was proposed.

Such an EBG structure is formed between a power layer and a ground layer to shield the power layer from noise. That is, the EBG structure is configured such that band-stop characteristics of blocking signal transmission at specific frequencies by the values of capacitance and inductance generated between an EBG cell and the ground layer are realized, thus preventing the noise transmitted between the power layer and the ground layer from being transferred in a band of specific frequencies.

However, in a PCB in which power layers for supplying different voltages are sequentially formed, when a conventional EBG structure is used, there occurs a problem in that transferred noise is bypassed through another transmission path (that is, a power layer in which an EBG cell is not formed), and thus band-stop characteristics are not realized.

In other words, as shown in FIG. 1, in a PCB in which power layers Vcc1_L4 and Vcc2_L3 for supplying different voltages are sequentially stacked, an EBG cell 110 is formed between the second power layer Vcc2_L3 and a ground layer GND_L1. Accordingly, transferred noise is bypassed via another transmission path, that is, the first power layer Vcc1_L4, and thus band-stop characteristics enabling noise to be blocked at a specific frequency (for example, frequency corresponding to −40 dB) are not realized, as shown in FIG. 2.

Meanwhile, in order to solve the above problem, there has been proposed a structure for blocking the movement path of noise by etching a copper (Cu) foil on a predetermined portion of a first power layer Vcc1_L4 formed in the shape of a plate, as shown in FIG. 3, wherein the predetermined portion corresponds to the area in which the EBG cell 120 of a second power layer Vcc2_L3 is formed, thus ensuring EBG characteristics.

However, the above structure of FIG. 3 is problematic in that, since part of the first power layer Vcc1_L4 is etched and disconnected, the bypassing channel of noise is blocked, and then the performance of EBG can be ensured, as shown in FIG. 4. However, the structure may enter a DC open state in which the supply of power from input to output is impossible.

### SUMMARY OF THE INVENTION

Accordingly, the present invention has been made keeping in mind the above problems occurring in the prior art, and the present invention is intended to provide a printed circuit board which is configured such that, when power layers for supplying different voltages are sequentially stacked, EBG cells are implemented as a double structure so that a first EBG cell formed between a first power layer and a ground layer is arranged within a second EBG cell formed between a second power layer and the ground layer, thus preventing a DC open state, realizing band-stop characteristics, and eliminating noise.

In accordance with an aspect of the present invention, there is provided a Printed Circuit Board (PCB), comprising a first power layer; a second power layer stacked on a top of the first power layer and configured to supply voltage different from that of the first power layer; a ground layer stacked on a top of the second power layer; a first Electromagnetic Band Gap (EBG) cell formed between the first power layer and the ground layer; and a second EBG cell formed between the second power layer and the ground layer.

In the PCB according to an embodiment of the present invention, the first power layer and the second power layer are sequentially stacked.

In the PCB according to an embodiment of the present invention, the first EBG cell comprises first EBG patches formed on the first power layer; a first EBG pattern formed on the ground layer; and first via holes formed between the first power layer and the ground layer so as to connect the first EBG patches to the first EBG pattern.

In the PCB according to an embodiment of the present invention, the second EBG cell comprises second EBG patches formed on the second power layer; a second EBG pattern formed on the ground layer; and second via holes formed between the second power layer and the ground layer so as to connect the second EBG patches to the second EBG pattern.

In the PCB according to an embodiment of the present invention, the first EBG pattern and the second EBG pattern are independently formed.

In the PCB according to an embodiment of the present invention, the second power layer is formed such that portions thereof in which the first via holes are formed are spaced apart from each other.

In the PCB according to an embodiment of the present invention, the first EBG cell is arranged within the second EBG cell.

In the PCB according to an embodiment of the present invention, the PCB further comprises a signal layer stacked between the ground layer and the second power layer.

In the PCB according to an embodiment of the present invention, the PCB further comprises a first dielectric layer stacked between the first power layer and the second power layer; a second dielectric layer stacked between the second power layer and a signal layer; and a third dielectric layer stacked between the signal layer and the ground layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram showing an example of a conventional PCB;

FIG. 2 is a graph showing the frequency response characteristics of the PCB of FIG. 1;

FIG. 3 is a diagram showing another example of a conventional PCB;

FIG. 4 is a graph showing the frequency response characteristics of the PCB of FIG. 3;

FIG. 5 is a diagram showing a PCB according to an embodiment of the present invention; and

FIG. 6 is a graph showing the frequency response characteristics of the PCB of FIG. 5.

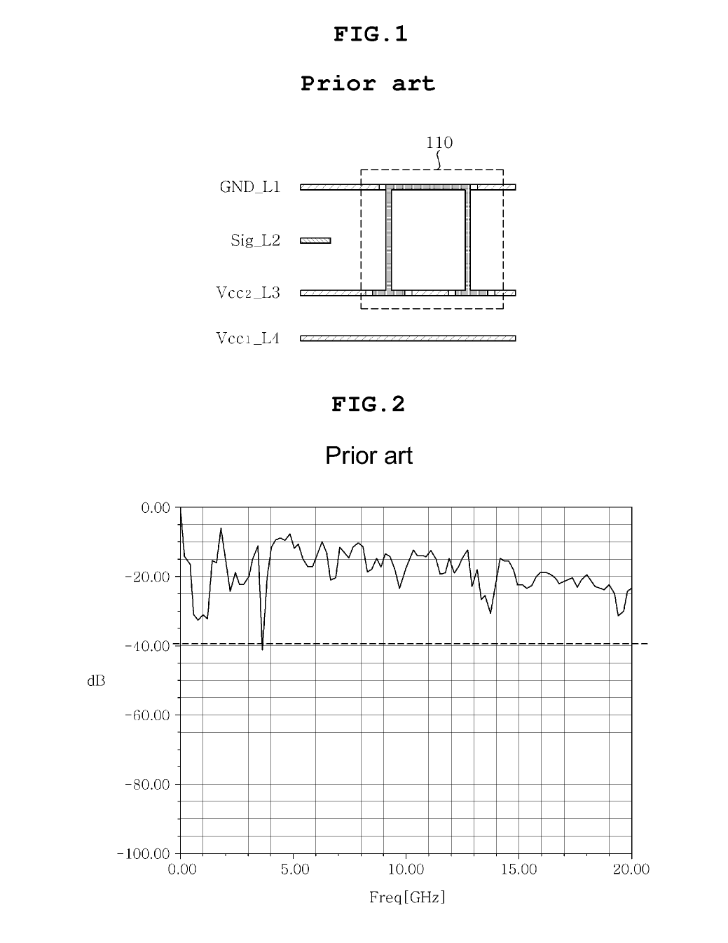

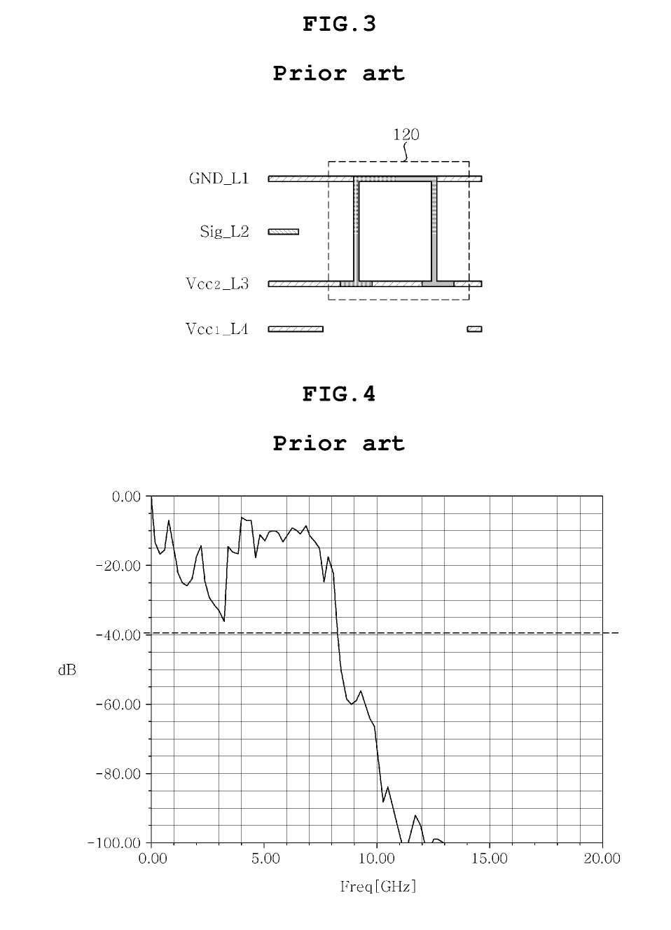

### DESCRIPTION OF THE PREFERRED EMBODIMENTS

Reference now should be made to the drawings, in which the same reference numerals are used throughout the different drawings to designate the same or similar components.

Hereinafter, embodiments of the present invention will be described in detail with reference to the attached drawings.

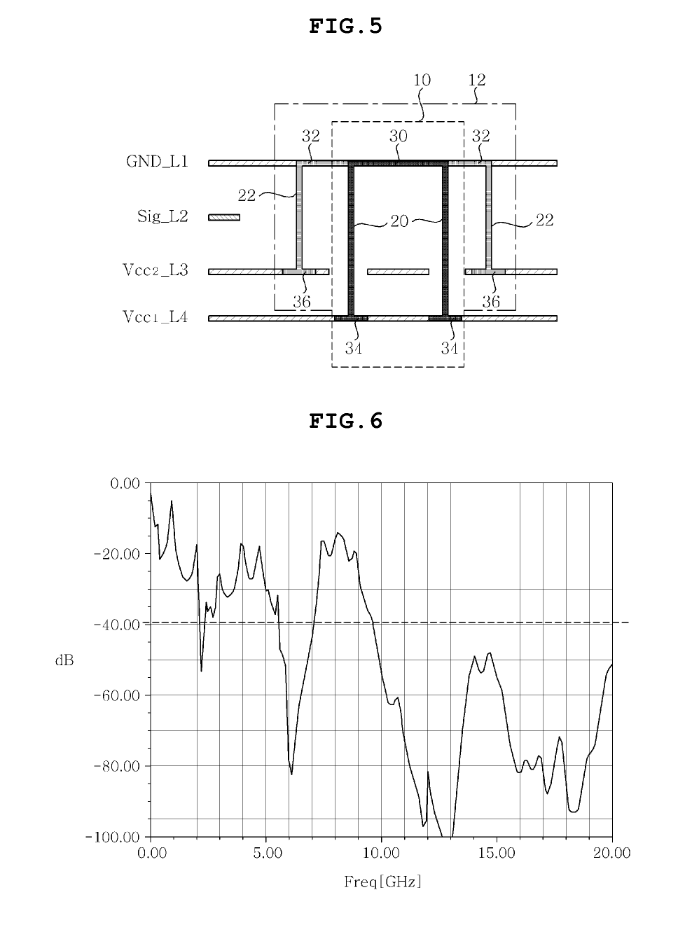

FIG. 5 is a diagram showing a Printed Circuit Board (PCB) according to an embodiment of the present invention.

Referring to FIG. 5, the PCB according to the embodiment of the present invention is formed such that a first power layer Vcc1_L4, a second power layer Vcc2_L3, a signal layer Sig_L2 and a ground layer GND_L1 are sequentially stacked.

Further, the PCB is formed such that a first dielectric layer is arranged between the first power layer Vcc1_L4 and the second power layer Vcc2_L3, a second dielectric layer is arranged between the second power layer Vcc2_L3 and the signal layer Sig_L2, and a third dielectric layer is arranged between the signal layer Sig_L2 and the ground layer GND_L1.

In this case, each of the dielectric layers is an insulating material generally used for the inter-layer insulation of the PCB, and may be made of, for example, a prepreg including epoxy resin.

Meanwhile, each of the first power layer Vcc1_L4 and the second power layer Vcc2_L3 is made of a conductive material, for example, gold, silver, copper, etc., and is formed in the shape of a plane.

The first power layer Vcc1_L4 and the second power layer Vcc2_L3 supply different voltages.

Meanwhile, a first Electromagnetic Band Gap (EBG) cell 10 is formed between the first power layer Vcc1_L4 and the ground layer GND_L1, and a second EBG cell 12 is formed between the second power layer Vcc2_L3 and the ground layer GND_L1.

In this case, the first EBG cell 10 is configured to include first EBG patches 34 formed on the first power layer Vcc1_L4, a first EBG pattern 30 formed on the ground layer GND_L1, and first via holes 20 formed between the first power layer Vcc1_L4 and the ground layer GND_L1 so as to electrically connect the first EBG patches 34 to the first EBG pattern 30.

Further, the second EBG cell 12 is configured to include second EBG patches 36 formed on the second power layer Vcc2_L3, a second EBG pattern 32 formed on the ground layer GND_L1, and second via holes 22 formed between the second power layer Vcc2_L3 and the ground layer GND_L1 so as to electrically connect the second EBG patches 36 to the second EBG pattern 32.

In this case, the first EBG pattern 30 and the second EBG pattern 32 are independently formed on the ground layer GND_L1.

Further, the first via holes 20 and the second via holes 22 are configured such that the inner walls thereof are formed as plated layers (for example, copper plated layers), or the via holes are filled with a conductive material (for example, conductive paste).

Meanwhile, the second power layer Vcc2_L3 is formed such that portions thereof in which the first via holes 20 are formed are disconnected, that is, spaced apart from each other in order to prevent the second power layer Vcc2_L3 from being electrically connected to the first via holes 20.

Further, the first EBG cell 10 is formed within the second EBG cell 12 so that the EBG cells form a double EBG structure.

In other words, in successive power layers, in order to prevent noise from being bypassed through one subsequent layer (for example, the first power layer Vcc1_L4) without passing through the EBG cell 12 designed on another layer (for example, the second power layer Vcc2_L3), the first via holes 20 are formed inside the second via holes 22 so that the via holes are designed as a dual structure composed of upper and lower layers in the middle of a noise path.

As a result, the first EBG cell 10 is formed to be arranged within the second EBG cell 12.

Meanwhile, the redundant regions of the first power layer Vcc1_L4 and the second power layer Vcc2_L3, that is, regions in which the first EBG cell 10 and the second EBG cell 12 are not formed, are formed in the shape of planes and are connected to the power. The redundant region of the ground layer GND_L1, that is, a region in which the first EBG cell 10 and the second EBG cell 12 are not formed is also formed in the shape of a plane and is connected to the ground.

Further, the signal layer Sig_L2 is formed such that regions thereof in which the first EBG cell 10 and the second EBG cell 12 are formed are disconnected.

In the PCB according to the embodiment of the present invention, the first EBG cell 10 formed between the first power layer Vcc1_L4 and the ground layer GND_L1 is arranged within the second EBG cell 12 formed between the second power layer Vcc2_L3 and the ground layer GND_L1 to allow the first EBG cell 10 and the second EBG cell 12 to have a double EBG structure even if the power layers for supplying different voltages are sequentially stacked. Accordingly, the PCB can block noise bypassed through one subsequent layer without passing through an EBG cell designed on another layer, thus realizing band-stop characteristics at frequencies equal to or greater than 9.6 GHz around a specific noise level (for example, −40 dB), as shown in FIG. 6. Furthermore, since the first power layer Vcc1_L4 is not disconnected, a DC open state can be prevented, thus enabling power to be supplied from input to output.

Although only a four-layer PCB has been described in the preferred embodiment of the present invention, those skilled in the art will appreciate that, even in a four-or-more layer structure in which a plurality of power layers is successively stacked, a DC open state can be prevented, and band-stop characteristics at specific frequencies can be realized through the above-described EBG structure.

Further, those skilled in the art will appreciate that the double EBG structure in the PCB according to the embodiment of the present invention is characterized in that differences may occur in operating frequency and noise level according to an arrangement method or a design format such as the design of the EBG itself.

The present invention is advantageous because, even if power layers for supplying different voltages are successively stacked, a first EBG cell formed between a first power layer and a ground layer is arranged within a second EBG cell formed between a second power layer and the ground layer to allow the first and second EBG cells to form a double EBG structure, so that noise bypassed through one subsequent layer without passing through an EBG cell designed on another layer can be blocked, thus realizing band-stop characteristics, and preventing a DC open state from occurring thanks to the prevention of the disconnection of the first power layer.

Although the preferred embodiments of the present invention have been disclosed for illustrative purposes, those skilled in the art will appreciate that various modifications, to additions and substitutions are possible, without departing from the scope and spirit of the invention as disclosed in the accompanying claims.

What is claimed is:

1. A Printed Circuit Board (PCB), comprising:
a first power layer;
a second power layer stacked on a top of the first power layer and configured to supply voltage different from that of the first power layer;
a ground layer stacked on a top of the second power layer;
a first Electromagnetic Band Gap (EBG) cell formed between the first power layer and the ground layer; and
a second EBG cell formed between the second power layer and the ground layer.

2. The PCB as set forth in claim 1, wherein the first power layer and the second power layer are sequentially stacked.

3. The PCB as set forth in claim 1, wherein the first EBG cell comprises:
first EBG patches formed on the first power layer;
a first EBG pattern formed on the ground layer; and
first via holes formed between the first power layer and the ground layer so as to connect the first EBG patches to the first EBG pattern.

4. The PCB as set forth in claim 3, wherein the second EBG cell comprises:
second EBG patches formed on the second power layer;
a second EBG pattern formed on the ground layer; and
second via holes formed between the second power layer and the ground layer so as to connect the second EBG patches to the second EBG pattern.

5. The PCB as set forth in claim 4, wherein the first EBG pattern and the second EBG pattern are independently formed.

6. The PCB as set forth in claim 3, wherein the second power layer is formed such that portions thereof in which the first via holes are formed are spaced apart from each other.

7. The PCB as set forth in claim 1, wherein the first EBG cell is arranged within the second EBG cell.

8. The PCB as set forth in claim 1, further comprising a signal layer stacked between the ground layer and the second power layer.

9. The PCB as set forth in claim 1, further comprising:
a first dielectric layer stacked between the first power layer and the second power layer;
a second dielectric layer stacked between the second power layer and a signal layer; and
a third dielectric layer stacked between the signal layer and the ground layer.
